(19) United States
(12) Patent Application Publication
(10) Pub. No.: US 2005/0208742 A1
(43) Pub. Date: Sep. 22, 2005

(54) OXIDIZED TANTALUM NITRIDE AS AN IMPROVED HARDMASK IN DUAL-DAMASCENE PROCESSING

(75) Inventors: William G. America, Kingston, NY (US); Larry Clevenger, LaGrangeville, NY (US); Andy Cowley, Wappingers Falls, NY (US); Timothy J. Dalton, Ridgefield, CT (US); Mark Hoinkis, Fishkill, NY (US); Kaushik A. Kumar, Beacon, NY (US); Douglas C. La Tulipe Jr., Danbury, CT (US)

Correspondence Address: INTERNATIONAL BUSINESS MACHINES CORPORATION;DEPT. 18G, BLDG. 300-482, 2070 ROUTE 52, HOPEWELL JUNCTION, NY, 12533, US

(73) Assignee: INTERNATIONAL BUSINESS MACHINES CORPORATION, Armonk, NY (US)

(21) Appl. No.: 10/708,648

(22) Filed: Mar. 17, 2004

(51) Int. Cl. H01L 21/3205; H01L 21/4763

(52) U.S. Cl. 438/586; 438/624

(57) ABSTRACT

A method of producing an oxidized tantalum nitride (TaOₓNₓ) hardmask layer for use in dual-damascene processing is described. Fine-line dual-damascene processing places competing, conflicting demands on the hardmask. Whereas critical dimension control needs a thicker hardmask, optical lithographic alignment is frustrated by the opacity of thick tantalum nitride (TaN). The technique solves the problem of TaN hardmask opacity with increasing thickness by oxidizing the TaN layer. Oxidation of the TaN hardmask increases the thickness of the hardmask to two to four times its original thickness and simultaneously increases its transparency by greater than ten times. This permits better CD control associated with a thicker hardmask while facilitating optical lithographic alignment.

### BACKGROUND OF INVENTION

The present invention relates generally to semiconductor devices, more particularly to dual-damascene processing in the fabrication of semiconductor devices, and still more particularly to hardmask materials for dual-damascene processing.

As integrated circuit density has increased, the former practice of using aluminum conductors for interconnections within integrated circuit devices have become a significant limiting factor. This is due, in large part, to aluminum's relatively poor performance as a conductor at the very small line widths associated with modern high-density integrated circuits. Similarly sized conductors formed of copper (Cu), which exhibits much lower resistivity than aluminum, are capable of performing reliably much higher current densities and are better suited to the newer fine-pitch design rules.

The use of copper interconnects, however, has necessitated new processing techniques. Direct patterning of copper conductors is generally impractical using modern processing techniques. Accordingly, copper conductors are typically formed using a dual-damascene process. In a typical dual-damascene process, trenches and vias are photolithographically created in a dielectric layer. Copper is then deposited into the trenches and vias, filling them. Any excess copper is then removed via a conventional planarization technique such as CMP (chemical-mechanical polishing).

In one dual-damascene processing scheme, tantalum nitride (TaN) is used as a hardmask (HM), which also serves as a line template. In this process, the etch scheme for defining trench patterns (Mx) utilizes the TaN HM. Critical dimension (CD) control for the lithographic process used to create these trenches (Mx Metallization level ‘x’) and vias (Vx Via level ‘x’) is heavily dependent on the thickness of the TaN hardmask. The patterns defined in the Mx lithography are etch-transferred to the TaN hardmask. This is followed by via-lithography and a subsequent dual-damascene etch. During the dual-damascene etch, the TaN hardmask is intended to preserve the etch patterns. However, for the etching processes necessitated by hybrid dielectric or inorganic dielectric materials, the TaN is eroded by the etch process, leading to loss of critical dimension (CD) control or “CD blowout”. CD control can be regained by increasing the thickness of the TaN hard-mask layer, but this increased thickness has the undesirable side-effect of decreasing the transparency of the TaN layer to a point where optical alignment of lithographic processes to underlying alignment features becomes difficult or impossible.

Where fine-line CD control is required, precise control of lithographic process alignment is also required. This presents two competing sets of requirements on the thickness of the TaN hardmask layer. Whereas precise photolithographic process alignment requires levels of optical transparency that can only be achieved with a thinner TaN hardmask layer, CD control considerations require a thicker TaN hardmask layer. As device geometry becomes smaller, the conflict between these competing requirements becomes greater, severely limiting the usefulness of TaN as a hardmask.

### SUMMARY OF INVENTION

The present inventive technique solves the problem of TaN hardmask opacity with increasing thickness by oxidizing the TaN layer. Oxidation of the TaN hardmask produces two desirable results. First, it increases the thickness of the hardmask to two to four times its original thickness. This permits better CD control, especially when etching hybrid dielectric or inorganic dielectric materials. Second, it increases the transparency of the TaN hardmask, which facilitates precise optical alignment of the lithographic processes, further enhancing CD control. The transparency of oxidized TaN hardmask over TaN is improved by a factor of greater than ten times (as measured in terms of a wafer quality number). In combination, these two results produce a hardmask that is capable of simultaneously satisfying the competing requirements of a thicker hardmask and greater hardmask transparency.

According to the invention, two distinct process paths can be employed to create the oxidized tantalum nitride hardmask. In a first process, the tantalum nitride layer is subjected to an oxidation process in its entirety, converting the entire tantalum nitride (TaN) layer to tantalumoxy-nitride (TaOₓNₓ). After oxidation, the oxidized tantalum nitride layer is lithographically etched to form trench openings therein, followed by normal dual-damascene via and trench formation. This process is referred to hereinafter as an “oxidize, then etch” methodology.

Alternatively, the tantalum nitride layer can be lithographically etched to form trench openings therein, prior to oxidation. After etching, the etched tantalum nitride layer is subjected to the oxidation process to form a patterned oxidized tantalum nitride layer. This process is referred to hereinafter as an “etch, then oxidize” methodology.

In dual-damascene processing, the tantalum nitride layer is a top-level hardmask layer on a “stack” comprising a base dielectric layer, a cap layer overlying the base dielectric, a dielectric layer overlying the cap layer, first and second hardmask layers (HM1 and HM2) overlying the dielectric layer, and the top-level TaN hardmask overlying the HM1 and HM2 layers. The dielectric layer can be a single layer organic or inorganic dielectric, or can be a multi-level hybrid dielectric. The base dielectric includes circuit elements (typically active silicon or conductors) to which electrical contact is to be made via the dual damascene process. The circuit elements are typically planarized with the base dielectric layer to produce a substantially flush surface.

According to an aspect of the invention, the oxidation process can be a combined thermal and plasma oxidation process. The oxidation environment is preferably provided in a chamber with a N₂O flow rate between 500 and 5000 sccm (standard cubic centimeters per minute) at a pressure between 1 and 10 Torr. Preferably the oxidation process employs a substrate temperature of between 250 degrees C. and 400 degrees C. with a plasma power of between 250 and 1000 Watts.

According to one embodiment of the invention, the method comprises providing a semiconductor wafer having a base dielectric layer, said base dielectric layer having circuit elements embedded therein and planarized flush with the surface thereof to which a subsequent electrical connection is to be made. A cap layer is formed over the base dielectric layer and circuit elements. A dielectric layer is formed over the cap layer. This dielectric layer can be a single layer organic or inorganic dielectric or a multi-level hybrid dielectric. Hardmask layers are formed over the dielectric layer and a tantalum nitride hardmask layer is formed over the hardmask layers. The tantalum nitride layer is lithographically patterned and is then subjected to an oxidation process as described above.

According to another embodiment of the invention, the method comprises providing a semiconductor wafer having a base dielectric layer, said base dielectric layer having circuit elements embedded therein and planarized flush with the surface thereof to which a subsequent electrical connection is to be made. A cap layer is formed over the base dielectric layer and circuit elements. A dielectric layer is formed over the cap layer. This dielectric layer can be a single layer organic or inorganic dielectric or a multi-level hybrid dielectric. Hardmask layers are formed over the dielectric layer and a tantalum nitride hardmask layer is formed over the hardmask layers. The tantalum nitride layer is oxidized to form oxidized tantalum nitride. The oxidized tantalum nitride layer is then lithographically patterned.

These two embodiments produce substantially equivalent resulting structures which can be further processed via normal dual-damascene methodology to complete the formation of trench and via openings, followed by deposition of the conductor material (preferably copper).

### BRIEF DESCRIPTION OF DRAWINGS

These and further features of the present invention will be apparent with reference to the following description and drawing, wherein:

FIG. 1 is a cross-sectional diagrams of an in-process semiconductor device illustrating a layer “stack-up” for dual-damascene processing with a TaN hardmask, in accordance with the invention.

FIG. 2 is a process flow diagram showing two possible process paths for producing an oxidized TaN (TaOₓNₓ) hardmask, in accordance with the invention.

FIGS. 3A-3D are cross-sectional diagrams of an in-process semiconductor device illustrating steps of a first process path to produce an oxidized TaN hardmask, in accordance with the invention.

FIGS. 4A-4E are cross-sectional diagrams of an in-process semiconductor device illustrating steps of a second process path to produce an oxidized TaN hardmask in accordance with the invention.

FIGS. 5A-5B are cross-sectional diagrams illustrating subsequent processing steps utilizing an oxidized TaN hardmask, in accordance with the invention.

### DETAILED DESCRIPTION

The present inventive technique employs oxidized tantalum nitride (TaN) as an improved hardmask for use in dual-damascene processing. By oxidizing a tantalum nitride hardmask (to produce TaOₓNₓ tantalum oxy-nitride), the thickness of the hardmask is increased by a factor of two to four times over unoxidized TaN, while simultaneously increasing the transparency of the hardmask by a factor of greater than ten times. The thicker TaOₓNₓ hardmask provides better critical dimension (CD) control against the etching processes used to etch hybrid or inorganic dielectrics. The increased transparency of the TaOₓNₓ hardmask permits accurate optical alignment of lithographic processes to underlying alignment features (typically formed in the base dielectric layer well below the hardmask layer).

The TaN hardmask is oxidized by means of the combination of thermal oxidation and N₂O plasma at low pressure. Preferably, a N₂O flow rate between 1000 and 2000 sccm at a chamber pressure between 1 Torr and 6 Torr provides the oxidation ambient environment. A plasma power between 250W (watts) and 1000W in combination with a substrate temperature between 250° C. and 400° C. is preferably employed as the oxidation process.

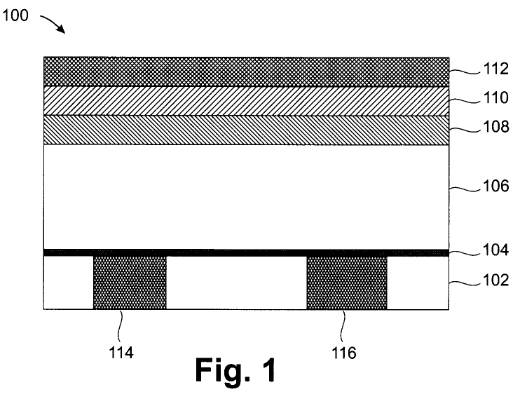

FIG. 1 is a cross-section diagram of a typical semiconductor wafer 100 showing a typical layer “stack-up” for processing according to the present inventive technique. A base dielectric layer 102 has formed within it circuit elements 114 and 116 to which subsequent connections are to be made via a dual-damascene process. The base dielectric layer 102 and the circuit elements 114 and 116 are planarized such that the surface of the base dielectric 102 is substantially planar (flat) and the circuit elements 114 and 116 are essentially flush with the planar surface of the base dielectric 102. This base dielectric layer 102 can be a bottom-level dielectric in which semiconductor structures are formed, or an intemediate-level dielectric in which intermediate-level interconnections (Mx) are formed. It can be either a single dielectric or a multi-layer hybrid dielectric. Accordingly, the circuit elements 114 and 116 can be active silicon or metal conductors. Those of ordinary skill in the art will immediately recognize the implication that this “starting” stack-up can be formed at any metallization level Mx, thereby permitting the present inventive technique to be repeated multiple times on any given wafer to form multiple interconnection layers.

Overlying the base dielectric 102 and circuit elements 114 and 116 is a cap layer 104. The cap layer 104 acts as a hermetic seal to protect the underlying structures (102, 114, 116) against damage and/or contamination (e.g., by moisture) in subsequent processing steps. Typically the cap layer 104 is SiCH, SiCOH, SiN, SiCNH, etc.

Overlying the cap layer 104 is a dielectric layer 106. The dielectric layer 106 can be a single-level organic or inorganic dielectric, or it can be a hybrid dielectric stack. In dual-damascene processes, it is common to use a hybrid dielectric stack to facilitate and control formation of trench and via openings.

Overlying the dielectric layer 106 is a first hardmask layer 108 (HM1). This HM1 layer 108 acts as a hermetic seal for the dielectric layer 106 and as a CMP (chem-mech polish) stop. It can be SiCOH, SiCNH, SiCH, SiN or other suitable material.

Overlying the HM1 layer 108 is a second hardmask layer 110 (HM2). This HM2 layer acts as a plasma rework barrier, and can be SiCOH, SiCNH, SiCH, SiN, SiO₂ or other suitable material.

Overlying the HM2 layer 110 is a tantalum nitride (TaN) top hardmask layer 112, which preserves lithographic patterning during subsequent trench etching by RIE (reactive ion etch).

The aforementioned oxidation of the TaN hardmask can be accomplished by two different process paths.

1) Etch, then oxidize (Post Mx RIE oxidation); or

2) Oxidize, then etch (Pre Mx RIE oxidation).

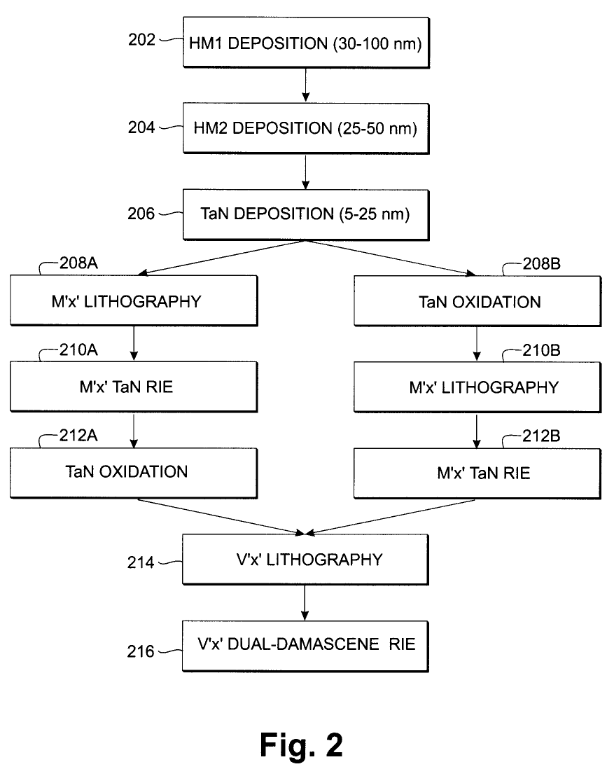

FIG. 2 is a process flow diagram illustrating the steps associated with these two process paths. In a first step 202, a first planar hardmask layer (HM1, e.g., 108, FIG. 1) is disposed over a dielectric layer (see e.g., 106, FIG. 1).

Typically, the HM1 layer is 30-100 nm (nanometers) in thickness and is formed of a suitable hermetic-seal/polish-stop material as described hereinabove with respect to FIG. 1. As described hereinabove, the dielectric layer can be either a single dielectric or a hybrid dielectric. In a second step, a second planar hardmask layer (HM2, e.g., 110, FIG. 1) is disposed over the first hardmask layer (HM1). Typically the HM2 layer is 25-50 nm thick and is formed of a suitable plasma barrier material as described hereinabove with respect to FIG. 1.

In a next step 206, a TaN top level hardmask is disposed over the HM2 layer, typically to a thickness of 5-25 nm.

At this point, the process flow diagram splits to show two separate possible process flows. A leftmost process flow (as illustrated) comprising process steps 208A, 210A and 212A illustrates the “etch, then oxidize” methodology. A rightmost process flow (as illustrated) comprising process steps 208B, 210B and 212B illustrated the “oxidize, then etch) methodology. The two process flows re-converge onto a common process flow at a process step 214.

Directing attention to the “etch, then oxidize” process flow (the leftmost process path in FIG. 2), in a process step 208A, Mx (metallization level ‘x’) lithographic photoresist patterning is performed to expose areas in which trench openings in the top-level TaN hardmask will be formed. In a next process step 210A, a reactive ion etch (RIE) is used to remove exposed areas of the TaN hardmask. The photoresist is then stripped. In a next process step 212A, the TaN hardmask is subjected to the thermal and plasma oxidation process described hereinabove. This process converts the TaN hardmask to TaOₓNₓ, thickening it by a factor of 2-4 times and simultaneously increasing its transparency (by greater than 10 times) and improving CD control for subsequent via etching steps.

Now directing attention to the “oxidize then etch” process flow (the rightmost process path in FIG. 2), in a process step 208B, the un-patterned (un-etched) TaN top level hardmask is subjected to the thermal and plasma oxidation process described hereinabove, thereby thickening the entire resultant TaOₓNₓ top hardmask layer and increasing its transparency before etching. In a next process step 210B, lithographic photoresist patterning is performed to expose areas of the TaOₓNₓ top-level hardmask in which trench openings will be formed. In a next process step 212B, the exposed areas of the TaOₓNₓ top-hardmask are etched to create trench openings therein. The photoresist is then stripped. In this series of process steps, top-level hardmask transparency is enchanced to improve lithographic alignment for both trench (Mx) and via (Vx) processing.

The “etch, then oxidize” process path ending in process step 212A and the “oxidize, then etch” process path ending in process step 212B produce essentially equivalent structures. At this point, the two process paths reconverge at a process step 214, wherein dual-damascene V‘x’ (via level ‘x’) lithography is performed, followed by a conventional dual-damascene RIE step 216 to form the vias (and complete the trenches).

Those of ordinary skill in the art will immediately understand that with the exception of the TaN top-level hardmask processes, the dual-damascene processes described herein are conventional dual-damascene processing steps, and that the present inventive technique can be adapted to any suitable dual-damascene process flow that employs a TaN top-level hardmask.

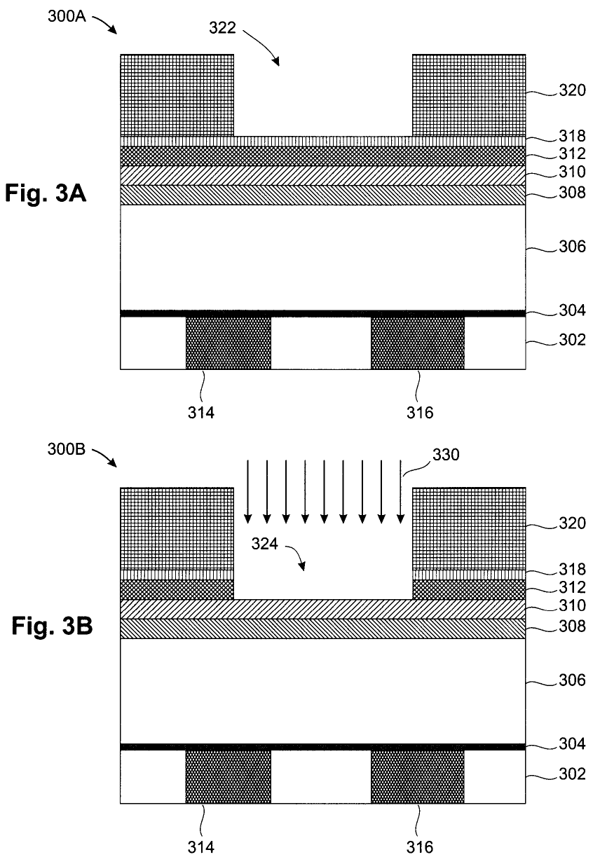

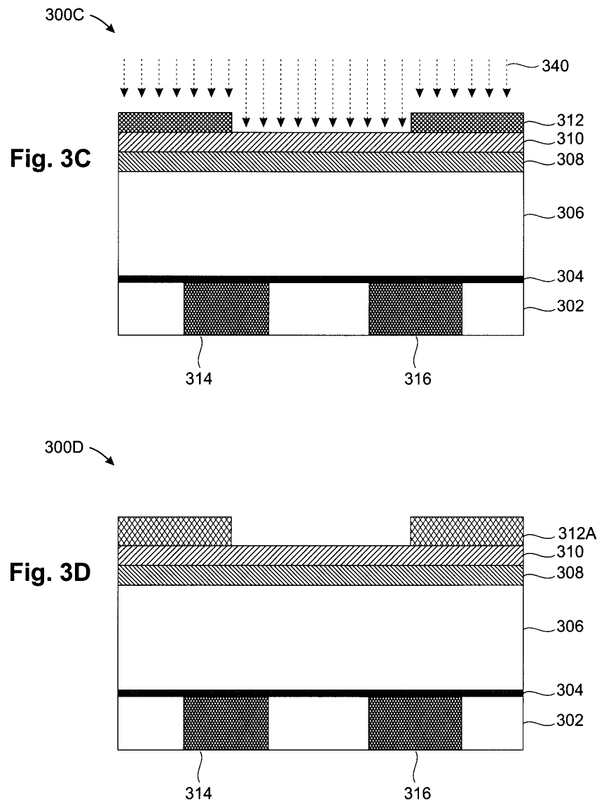

FIGS. 3A-3D are cross-sectional diagrams of an inprocess semiconductor device illustrating the “etch, then oxide” methodology for producing an oxidized TaN hardmask. In the figures, reference numbers 3xx generally correspond to similar reference numbers 1xx in FIG. 1. That is, base dielectric 302 generally corresponds to base dielectric 102; cap layer 304 generally corresponds to cap layer 104, etc. The characteristics of corresponding elements in FIGS. 1 and 3A-D are substantially identical.

In FIG. 3A, a semiconductor wafer at a first step of processing 300A is shown in cross-section. A base dielectric 302 includes embedded, planarized circuit elements 314 and 316 to which connections are to be made via a subsequent dual-damascene process. A cap layer 304 overlies the base dielectric layer 302. A dielectric layer 306 (which may be a single dielectric or hybrid dielectric) overlies the cap layer. HM1 and HM2 layers 308 and 310 overlie the dielectric layer 306. A TaN hardmask layer 312 overlies the HM2 layer 310. An antireflective coating (ARC) 318 is disposed over the TaN hardmask 312. A patterned photoresist layer 320 is disposed over the ARC 318, with an opening 322 that exposes a portion of the TaN hardmask layer 312 (through the ARC 318).

FIG. 3B is a cross-sectional diagram of a semiconductor wafer 300B corresponding to the semiconductor wafer 300A of FIG. 3A after subjecting it to a RIE (reactive ion etch) process 330 (indicated by arrows). The RIE process is highly anisotropic and etches away the exposed ARC 318 and TaN hardmask 312 to create a trench opening 324 in the TaN hardmask 312.

FIG. 3C is a cross-sectional diagram of a semiconductor wafer 300C corresponding to the semiconductor wafer 300B of FIG. 3B after stripping the photoresist 320 and ARC 318 to expose the unetched portions of the TaN hardmask layer 312. The hardmask is then subjected to a thermal and plasma oxidation process 340 (as described hereinabove). This results in the cross-sectional diagram of FIG. 3D which shows a semiconductor wafer 300D corresponding to the semiconductor wafer 300C of FIG. 3C after oxidation, exhibiting a thickened top level hardmask layer 312A of TaOₓNₓ. The thickened hardmask layer 312A also exhibits increased optical transparency as compared to the unoxidized top-level TaN hardmask 312.

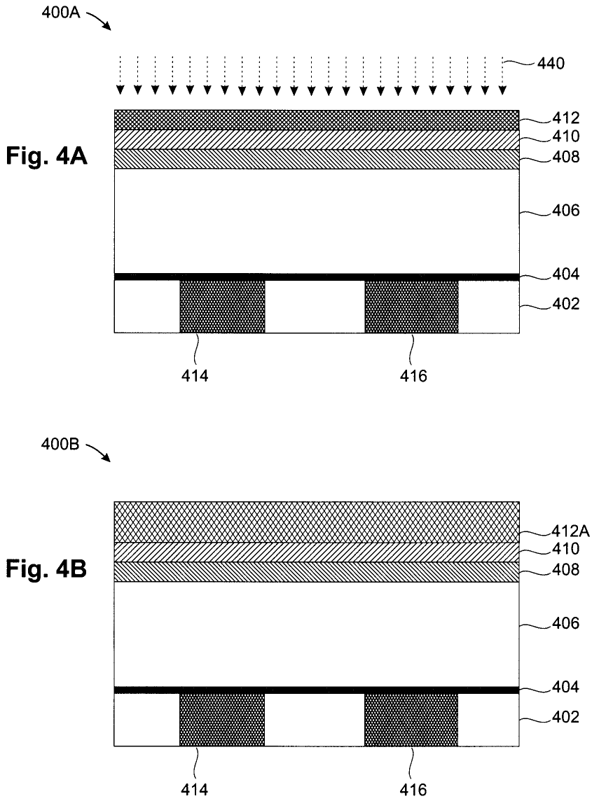

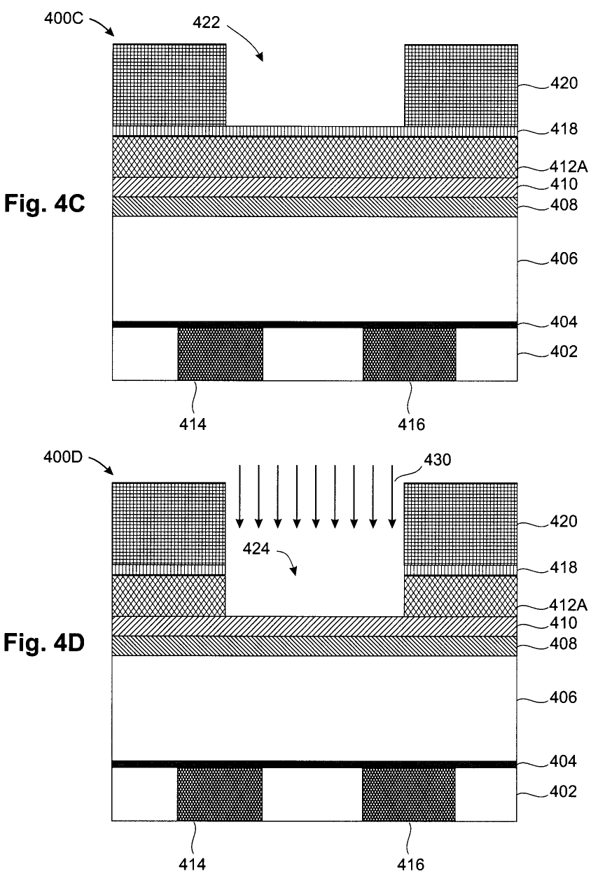

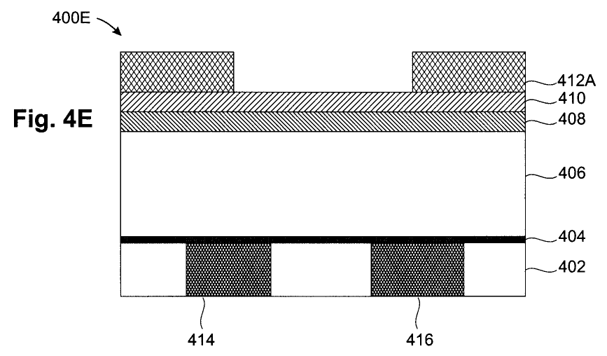

FIGS. 4A-4E are cross-sectional diagrams of an inprocess semiconductor device illustrating the “oxidize, then etch” methodology for producing an oxidized TaN hardmask. In the figures, reference numbers 4xx generally correspond to similar reference numbers 1xx in FIG. 1. That is, base dielectric 402 generally corresponds to base dielectric 102; cap layer 404 generally corresponds to cap layer 104, etc. The characteristics of corresponding elements in FIGS. 1 and 4A-E are substantially identical.

In FIG. 4A, a semiconductor wafer at a first step of processing 400A is shown in cross-section. A base dielectric 402 includes embedded, planarized circuit elements 414 and 416 to which connections are to be made via a subsequent dual-damascene process. A cap layer 404 overlies the base dielectric layer 402. A dielectric layer 406 (which may be a single dielectric or hybrid dielectric) overlies the cap layer. HM1 and HM2 layers 408 and 410 overlie the dielectric layer 406. A TaN hardmask layer 412 overlies the HM2 layer 410. The TaN hardmask 412 is subjected to a thermal and plasma oxidation process 440 as described hereinabove.

FIG. 4B is a cross-sectional diagram of a semiconductor wafer 400B corresponding to the semiconductor wafer 400A of FIG. 4A after oxidation (440). In the Figure, the TaN hardmask 412 (FIG. 4A) has been converted to a thicker TaOₓNₓ hardmask 412A by the process of oxidation, enhancing its optical transparency in the process.

FIG. 4C is a cross-sectional diagram of a semiconductor wafer 400C corresponding to the semiconductor wafer 400B of FIG. 4B after disposing an antireflective coating 418 (ARC) and patterned photoresist layer 420 over the converted TaOₓNₓ hardmask layer 412A. An opening 422 in the patterned photoresist layer 420 exposes a portion of the TaOₓNₓ hardmask 412A (through the ARC 418) in which a trench opening will be formed.

FIG. 4D is a cross-sectional diagram of a semiconductor wafer 400D corresponding to the semiconductor wafer 400C of FIG. 4C after subjecting it to a reactive ion etch process 430 (RIE) to create a trench opening 424 in the TaOₓNₓ hardmask layer.

FIG. 4E is a cross-sectional diagram of a semiconductor wafer 400E corresponding to the semiconductor wafer 400D of FIG. 4D after stripping the ARC (418) and photoresist layer 420. Note that the wafer 400E is essentially equivalent at this point in processing to the wafer 300D shown and described hereinabove with respect to FIG. 3D.

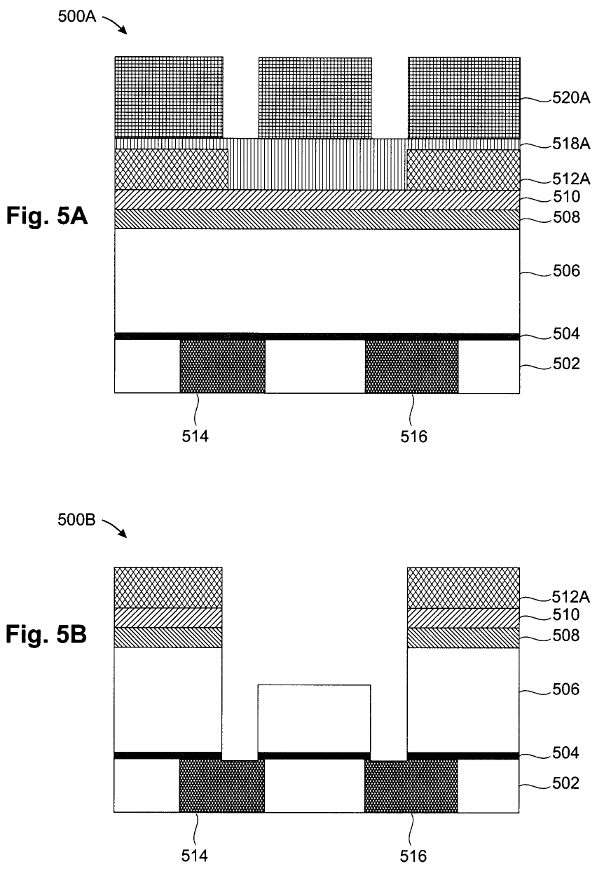

At this point in processing, the two methodologies (shown in FIG. 2 and described in FIGS. 3A-D and 4A-E) converge. FIGS. 5A-5B are cross-sectional diagrams illustrating subsequent processing steps utilizing the oxidized TaN hardmask. In the figures, reference numbers 5xx generally correspond to similar reference numbers 1xx in FIG. 1, similar reference number 3xx in FIGS. 3A-3D and to similar reference numbers 4xx in FIGS. 4A-4E. That is, base dielectric 502 generally corresponds to base dielectric 102; cap layer 504 generally corresponds to cap layer 104, etc. The characteristics of corresponding elements in FIGS. 1, FIGS. 3A-D, FIGS. 4A-E and FIG. 5A-B are substantially identical.

FIG. 5A is a cross-sectional diagram of a semiconductor wafer 500A corresponding to a semiconductor wafer 300D (FIG. 3D) or 400E (FIG. 4E) after formation of a planarized ARC layer 518A and Vx (via level ‘x’) patterned photoresist 520A over A patterned TaOₓNₓ hardmask layer 512A (compare 312A, FIG. 3D and 412A, FIG. 4E). As in the previous Figures, the wafer 500A exhibits a base dielectric 502 that includes embedded, planarized circuit elements 514 and 516 to which connections are to be made via subsequent dual-damascene processing. A cap layer 504 overlies the base dielectric layer 502. A dielectric layer 506 (which may be a single dielectric or hybrid dielectric) overlies the cap layer. HM1 and HM2 layers 508 and 510 overlie the dielectric layer 506. A patterned TaOₓNₓ hardmask layer 512A overlies the HM2 layer 510.

FIG. 5B is a cross-sectional diagram of a semiconductor wafer 500B corresponding to the semiconductor wafer 500A of FIG. 5A at a later stage of dual-damascene processing wherein vias and trenches have been fully formed through to the circuit elements 514 and 516. At this point, the wafer 500B is ready for deposition of the conductor material (i.e., Cu) in the trenches/vias.

Although the invention has been shown and described with respect to a certain preferred embodiment or embodiments, certain equivalent alterations and modifications will occur to others skilled in the art upon the reading and understanding of this specification and the annexed drawings. In particular regard to the various functions performed by the above described components (assemblies, devices, circuits, etc.) the terms (including a reference to a“means”) used to describe such components are intended to correspond, unless otherwise indicated, to any component which performs the specified function of the described component (i.e., that is functionally equivalent), even though not structurally equivalent to the disclosed structure which performs the function in the herein illustrated exemplary embodiments of the invention. In addition, while a particular feature of the invention may have been disclosed with respect to only one of several embodiments, such feature may be combined with one or more features of the other embodiments as may be desired and advantageous for any given or particular application.

1. A method of forming an oxidized tantalum nitride hardmask for dual damascene processing, comprising:
providing a semiconductor wafer, said wafer comprising:
a base dielectric layer;
a cap layer overlying the base dielectric layer;
a dielectric layer overlying the cap layer;
one or more hardmask layer overlying the dielectric layer; and
a tantalum nitride layer overlying the hardmask layers;
subjecting the tantalum nitride layer to an oxidation process to convert said tantalum nitride layer to oxidized tantalum nitride (TaOₓNₓ ).

2. A method according to claim 1, wherein the base dielectric layer includes planarized circuit elements to which an electrical connection is to be made.

3. A method according to claim 1, wherein the dielectric layer is a single dielectric.

4. A method according to claim 1, wherein the dielectric layer is a hybrid dielectric.

5. A method according to claim 1, wherein the dielectric layer is a hybrid dielectric.

6. A method according to claim 1, wherein the oxidation process is a combined thermal and plasma oxidation process.

7. A method according to claim 1, further comprising creating a patterned photoresist layer and etching the tantalum nitride layer prior to oxidation.

8. A method according to claim 1, further comprising creating a patterned photoresist layer and etching the oxidized tantalum nitride layer after the oxidation process.

9. A dual-damascene method of processing a semiconductor wafer, comprising:
providing a semiconductor wafer having a base dielectric layer, said base dielectric layer having circuit elements embedded therein and planarized flush with the surface thereof to which a subsequent electrical connection is to be made;
forming a cap layer over the base dielectric layer and circuit elements;
forming a dielectric layer over the cap layer;
forming a first hardmask layer (HM1) over the dielectric layer;
forming a second hardmask layer (HM2) over the first hardmask layer;
forming a tantalum nitride layer over the second hardmask layer;
lithographically etching the tantalum nitride layer to form trench openings therein; and
subjecting the etched tantalum nitride layer to an oxidation process to form an oxidized tantalum nitride layer.

10. A method according to claim 9, wherein the dielectric layer is a single dielectric layer.

11. A method according to claim 9, wherein the dielectric layer is a hybrid dielectric layer.

12. A method according to claim 9 wherein the oxidation process is a thermal and plasma oxidation process.

13. A method according to claim 12 wherein the oxidation process further comprises:
providing an oxidation environment with a N₂O flow rate between 500 and 5000 sccm at a chamber pressure between 1 and 10 Torr;
providing a wafer substrate temperature between 250 degrees C. and 400 degrees C.; and
providing a plasma power between 250 Watts and 1000 Watts.

14. A dual-damascene method of processing a semiconductor wafer, comprising:
providing a semiconductor wafer having a base dielectric layer, said base dielectric layer having circuit elements embedded therein and planarized flush with the surface thereof to which a subsequent electrical connection is to be made;
forming a cap layer over the base dielectric layer and circuit elements;
forming a dielectric layer over the cap layer;
forming a first hardmask layer (HM1) over the dielectric layer;
forming a second hardmask layer (HM2) over the first hardmask layer;
forming a tantalum nitride layer over the second hardmask layer;
subjecting the tantalum nitride layer to an oxidation process to form an oxidized tantalum nitride layer; and
lithographically etching the oxidized tantalum nitride layer to form trench openings therein.

15. A method according to claim 14, wherein the dielectric layer is a single dielectric layer.

16. A method according to claim 14, wherein the dielectric layer is a hybrid dielectric layer.

17. A method according to claim 14, wherein the oxidation process is a thermal and plasma oxidation process.

18. A method according to claim 17, wherein the oxidation process comprises:
providing an oxidation environment with a N₂O flow rate between 500 and 5000 sccm at a chamber pressure between 1 and 10 Torr;
providing a wafer substrate temperature between 250 degrees C. and 400 degrees C.; and
providing a plasma power between 250 Watts and 1000 Watts.
